(19) United States
(12) Patent Application Publication
(10) Pub. No.: US 2012/0015474 A1
(43) Pub. Date: Jan. 19, 2012

(54) METHOD FOR FABRICATING SILICON HETEROJUNCTION SOLAR CELLS

(76) Inventors: Yung-Chun Wu, Hsinchu City (TW); Shih-Hsien Yang, Taichung City (TW)

(21) Appl. No.: 12/838,883

(22) Filed: Jul. 19, 2010

(51) Int. Cl. H01L 31/18

(52) U.S. Cl. 438/96; 257/E31.047

(57) ABSTRACT

The present invention discloses a method for fabricating a silicon heterojunction solar cell. The silicon heterojunction solar cell according to the present invention comprises a first conductive silicon substrate; a first intrinsic silicon layer and a second intrinsic silicon layer respectively formed on two sides of the first conductive silicon substrate and jointed with the first conductive silicon substrate to form silicon heterojunctions; a second conductive silicon layer and a first conductive heavily-doped silicon layer respectively formed on the first intrinsic silicon layer and the second intrinsic silicon layer, wherein the second conductive silicon layer and the first conductive heavily-doped silicon layer are formed via an ion implantation method, whereby is optimized the thickness and doped quality of the second conductive silicon layer and the first conductive heavily-doped silicon layer.

### FIELD OF THE INVENTION

The present invention relates to a method for fabricating silicon heterojunction solar cells, and particularly to a method for fabricating a silicon heterojunction solar cell, which can reduce the fabrication cost and increase the photoelectric conversion efficiency.

### BACKGROUND OF THE INVENTION

With the advance of science and technology, civilization evolution and population growth, energy is being massively consumed. Because the natural resources, such as petroleum, natural gas and coal, are extremely limited, saving power and developing alternative energies have become the focal subject of the world. As solar energy is eternally-sustainable and spread everywhere, solar energy has been the mainstream of alternative energies.

A solar cell is a photoelectric element to convert solar energy into electric energy. The simplest solar cell structure comprises a P-type semiconductor layer and an N-type semiconductor layer to form a PN junction. When the sunlight illuminates the solar cell, the electrons of the semiconductor layers will be excited to move toward the N-type semiconductor layer due to the built-in voltage, and the holes move toward the P-type semiconductor layer. While the P-type and N-type semiconductor layers are connected with an external circuit, current occurs. The abovementioned process of converting light energy into electric current is so-called photovoltaic effect.

Refer to FIG. 1 for a diagram schematically showing the structure of a silicon heterojunction solar cell proposed by the Sanyo Electric Company in Japan. The conventional silicon heterojunction solar cell 1 comprises an N-type single crystalline silicon substrate 11. A first intrinsic amorphous silicon layer 12 and a second intrinsic amorphous silicon layer 13 are respectively formed on two sides of the N-type single crystalline silicon substrate 11. A P-type amorphous silicon layer 14 and an N⁺-type amorphous silicon layer 15 are respectively formed on the external sides of the first intrinsic amorphous silicon layer 12 and second intrinsic amorphous silicon layer 13. A first TCO (Transparent Conductive Oxide) layer 16 and a second TCO layer 17 are respectively formed on the external sides of the P-type amorphous silicon layer 14 and N⁺-type amorphous silicon layer 15. A first electrode layer 18 and a second electrode layer 19 are respectively formed on the external sides of the first TCO layer 16 and second TCO layer 17. As the abovementioned solar cell contains a silicon heterojunction and intrinsic silicon layers, it is called the HIT solar cell (Heterojunction with Intrinsic Thin-layer solar cell). The photoelectric conversion efficiency of the HIT solar cell reaches as high as 23%. The HIT solar cell further has an advantage of reduced fabrication cost because it can be jointed at a low temperature about 200° C. Therefore, the HIT solar cell has won much attention since it entered the market in 1997.

In the conventional HIT solar cell, the P-type amorphous silicon layer 14 and the N⁺-type amorphous silicon layer 15 respectively have a very thin thickness of only about several to tens nanometers. To incorporate with the low-temperature process, the P-type amorphous silicon layer 14 and the N⁺-type amorphous silicon layer 15 are usually formed with the PECVD (Plasma Enhanced Chemical Vapor Deposition) method. However, the PECVD method is hard to form a very thin film in the event that a film has only several nanometers. In such a case, the thickness and doped concentration are hard to control. Further, the film may be uneven or disappeared in some areas. The quality of the amorphous silicon layers is a problem that the related field is eager to overcome because it is critical to the photoelectric conversion efficiency of solar cells.

### SUMMARY OF THE INVENTION

One objective of the present invention is to provide a method for fabricating a silicon heterojunction solar cell to accurately control the film thickness and the doped accuracy of the doped layer, whereby is promoted the yield rate and photoelectric conversion efficiency of the silicon heterojunction solar cells.

To achieve the abovementioned objective, the present invention proposes a method for fabricating a silicon heterojunction solar cell, which comprises steps of: preparing a first conductive crystalline silicon substrate; respectively forming a first silicon layer and a second silicon layer on two sides of the first conductive crystalline silicon substrate, whereby a silicon heterojunction is formed between the first silicon layer and the first conductive crystalline silicon substrate, and another silicon heterojunction is formed between the second silicon layer and the first conductive crystalline silicon substrate; forming a second conductive silicon layer on a portion of the external side of the first silicon layer and forming a first conductive heavily-doped silicon layer on a portion of the external side of the second silicon layer by ion implanting on the first silicon layer and the second silicon layer; forming a first TCO (Transparent Conductive Oxide) layer on the second conductive silicon layer; and respectively forming a first electrode layer and a second electrode layer on the first TCO layer and the first conductive heavily-doped silicon layer.

The method for fabricating a silicon heterojunction solar cell of the present invention can accurately control the doped concentrations of the P-type silicon layer and the N⁺-type silicon layer even though they have very thin thicknesses. The present invention can solve the conventional problems of uneven film thickness and the doped concentration. Below, the embodiments, in cooperation with the drawings, are used to describe the technical contents of the present invention in detail.

### BRIEF DESCRIPTION OF THE DRAWINGS

The embodiments of the present invention are described in cooperation with the following drawings.

FIG. 1 is a diagram schematically showing the structure of a conventional silicon heterojunction solar cell;

FIG. 2 is a flowchart of a method for a fabricating silicon heterojunction solar cell according to one embodiment of the present invention; and

FIGS. 3A-3H are sectional views schematically showing the process of fabricating a silicon heterojunction solar cell according to one embodiment of the present invention.

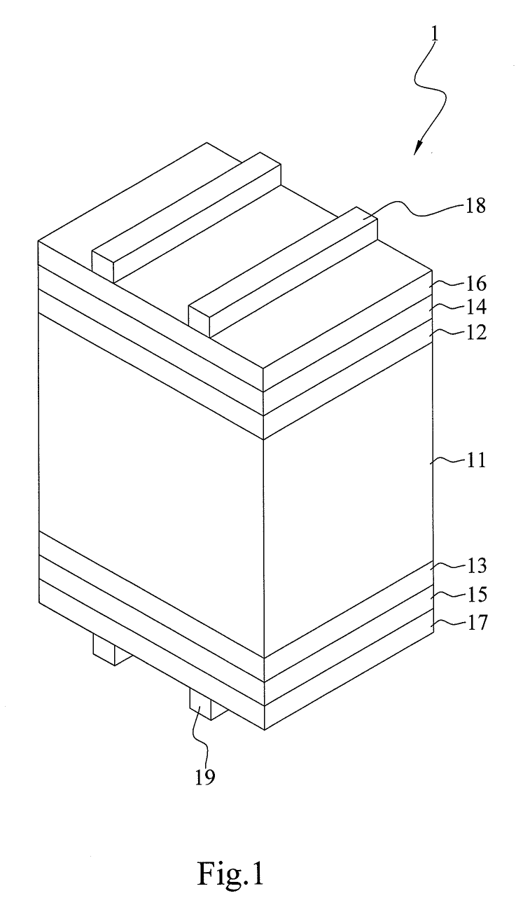

### DETAILED DESCRIPTION OF THE PREFERRED EMBODIMENTS

The technical contents of the present invention are described in detail in accompany with the drawings below.

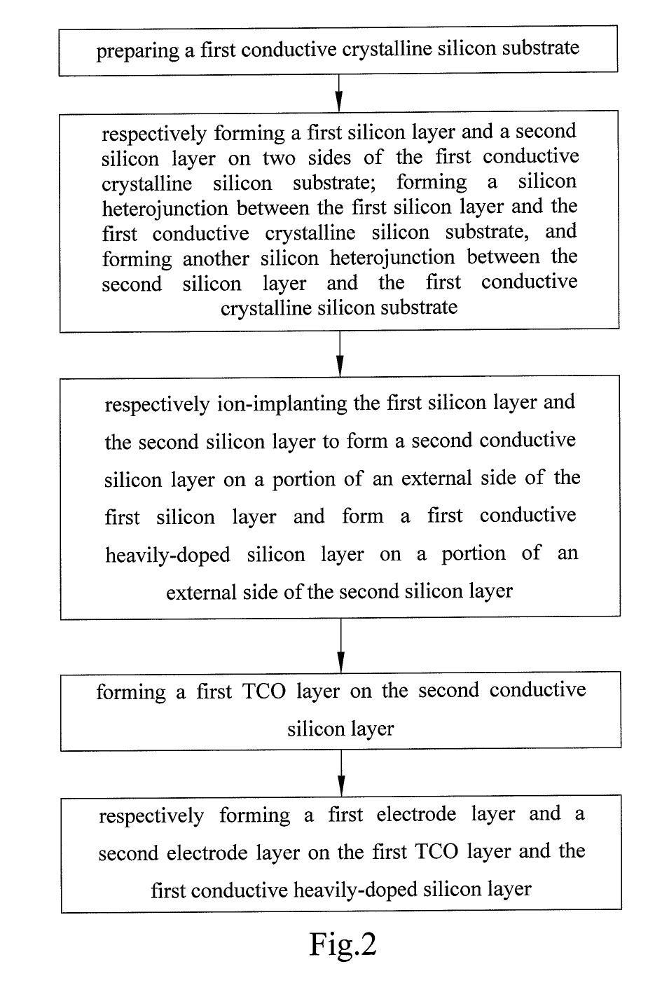

Refer to FIG. 2 for a flowchart of a method for a fabricating silicon heterojunction solar cell according to one embodiment of the present invention. The present invention proposes a method for fabricating a silicon heterojunction solar cell, which comprises steps of: fabricating a first conductive crystalline silicon substrate; respectively forming a first silicon layer and a second silicon layer on two sides of the first conductive crystalline silicon substrate, wherein a silicon heterojunction is formed between the first silicon layer and the first conductive crystalline silicon substrate, and another silicon heterojunction is formed between the second silicon layer and the first conductive crystalline silicon substrate; forming a second conductive silicon layer on a portion of the external side of the first silicon layer and forming a first conductive heavily-doped silicon layer on a portion of the external side of the second silicon layer by ion implanting on the first silicon layer and the second silicon layer; forming a first TCO (Transparent Conductive Oxide) layer on the second conductive silicon layer; and respectively forming a first electrode layer and a second electrode layer on the first TCO layer and the first conductive heavily-doped silicon layer.

It should be explained particularly that the above-mentioned “first conductive” and “second conductive” refer to “N-type doped” and “P-type doped”. When the “first conductive” is the “N-type”, the “second conductive” is the “P-type”. When the “first conductive” is the “P-type”, the “second conductive” is the “N-type”. Further, the so-called “heavily-doped” refers to “N⁺-type doped” or “P⁺-type doped”. For convenience of description and understanding, the “first conductive” is set to be the “N-type” and the “second conductive” is set to be the “P-type” in the following embodiments. However, the present invention is not limited by the settings or the following embodiments.

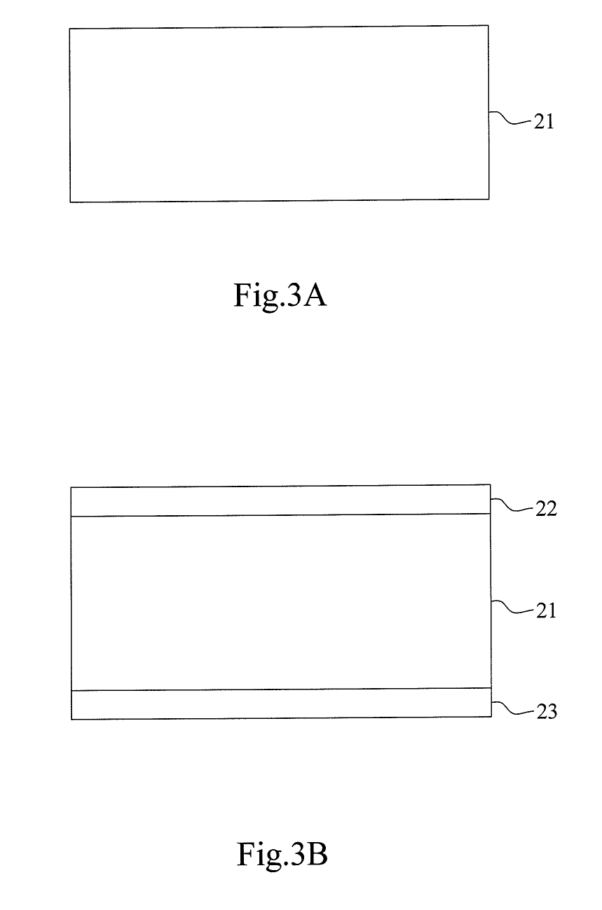

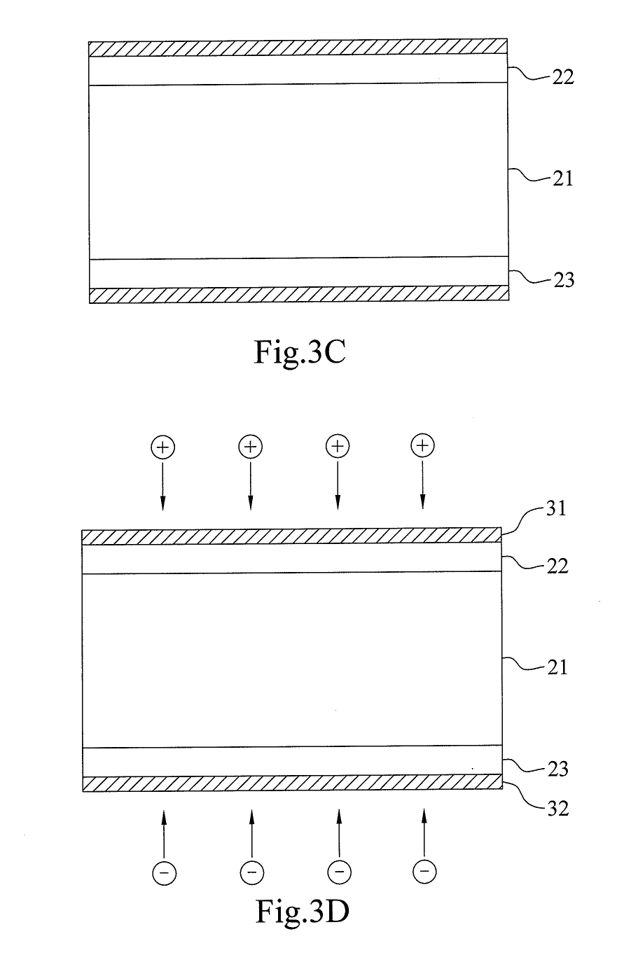

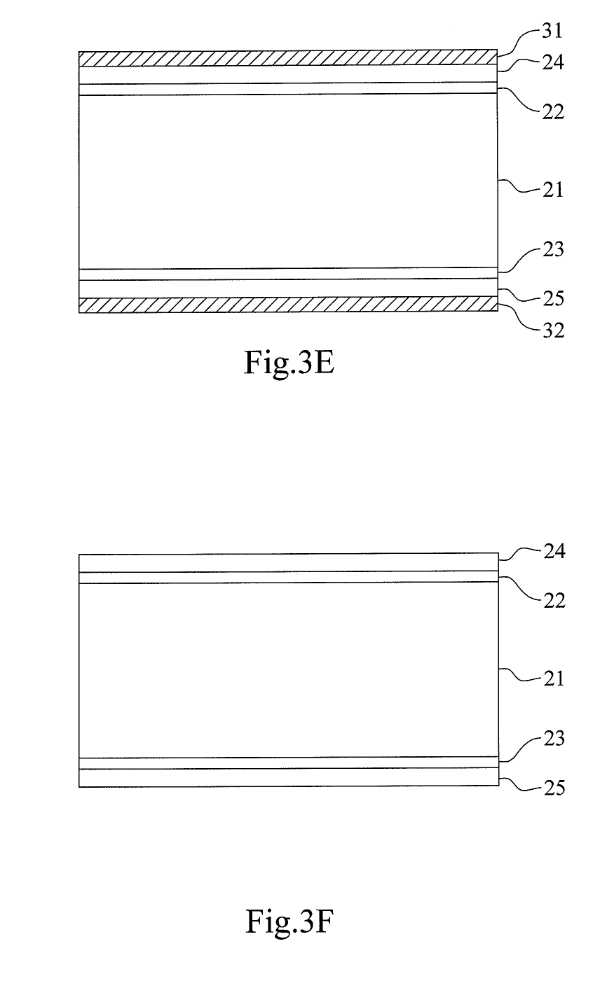

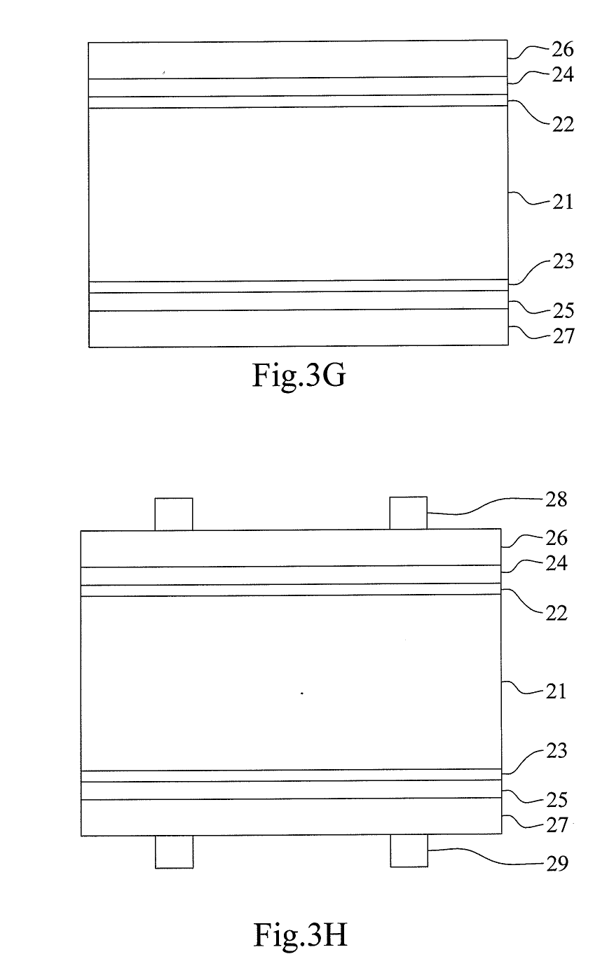

Refer to FIGS. 3A-3H for sectional views schematically showing the process of fabricating a silicon heterojunction solar cell according to one embodiment of the present invention. Firstly, prepare an N-type crystalline silicon substrate 21, as shown in FIG. 3A. The N-type crystalline silicon substrate 21 may be but not limited to an N-type single crystalline silicon substrate or an N-type polycrystalline silicon substrate, which has a thickness of about 200-600 μm. Next, as shown in FIG. 3B, respectively form a first silicon layer 22 and a second silicon layer 23 on two sides of the N-type crystalline silicon substrate 21, wherein either of the first silicon layer 22 and the second silicon layer 23 is an amorphous silicon layer or a polycrystalline silicon layer, whereby a silicon heterojunction is formed between the first silicon layer 22 and the N-type crystalline silicon substrate 21, and another silicon heterojunction is formed between the second silicon layer 23 and the N-type crystalline silicon substrate 21. In one embodiment, the N-type crystalline silicon substrate 21 is an N-type single crystalline silicon substrate; the first and second silicon layers 22 and 23 are intrinsic (undoped) amorphous silicon layers respectively having a thickness of 0.3-15 nm.

The present invention does not particularly limit the method to form the first and second silicon layers 22 and 23. Any existing film-deposition technology in the semiconductor field can be used to form the first and second silicon layers 22 and 23. In one embodiment, the first and second silicon layers 22 and 23 are formed with an LPCVD (Low Pressure Chemical Vapor Deposition) method. In the LPCVD process, wash the N-type crystalline silicon substrate 21 with the standard RCA procedures firstly; next, place the N-type crystalline silicon substrate 21 in an LPCVD furnace, and simultaneously deposit the first amorphous silicon layer 22 and the second amorphous silicon layer 23 on two sides of the N-type crystalline silicon substrate 21. The abovementioned LPCVD process has a reaction equation: SiH₄(g)→Si(s)+2H₂(g). The abovementioned process is undertaken at a temperature of 120-600° C. under a pressure of 0.1-500 mTorr.

Next, as shown in FIG. 3D and FIG. 3E, respectively form a P-type silicon layer 24 and an N⁺-type silicon layer 25 on parts of the external sides of the first and second silicon layers 22 and 23 by ion implanting. Meanwhile, the external parts of the P-type silicon layer 24 and the N⁺-type silicon layer 25 of the first and second silicon layers 22 and 23 or the part of the N-type crystalline silicon substrate 21 adjacent to the first and second silicon layers 22 and 23 become an intrinsic silicon layer in substance.

It should be explained particularly: In the case that the first and second silicon layers 22 and 23 are intrinsic silicon layers, the first and second silicon layers 22 and 23 neighboring the N-type crystalline silicon substrate 21 remain original intrinsic silicon in substance after the P-type silicon layer 24 and N⁺-type silicon layer 25 are formed by ion implanting. Contrarily, in the case that the first silicon layer 22 is N-type silicon layer, and after P-type ions are implanted into the first silicon layer 22, the P-type silicon layer 24 is formed on the external side of the first silicon layer 22 and the portion of the first silicon layer 22 neighboring the N-type crystalline silicon substrate 21 also becomes an intrinsic silicon layer because of the neutralization of positive and negative charges. Therefore, the present invention does not limit that the first and second silicon layers 22 and 23 should be intrinsic silicon layers.

After ion implantation, a high-temperature (900-1100° C.) thermal annealing is undertaken to bond the implanted ions to atoms of the first and second silicon layers 22 and 23 and reduce the stress and defects. In one embodiment, a Group III element, such as boron atom or boron fluoride (BF₂), is adopted as the ion to be implanted into the first silicon layer 22; a Group V element, such as arsenic atom, is adopted as the ion to be implanted into the second silicon layer 23.

In one embodiment, a first silicon oxide layer 31 and a second silicon oxide layer 32 are respectively formed on the first and second silicon layers 22 and 23 to function as the buffer layers for ion implantation before the first and second silicon layers 22 and 23 are ion implanted by an ion implanter. After ion implantation is completed, the first and second silicon oxide layers 31 and 32 are removed with a wet etching method (such as with the BOE (Buffered Oxide Etch) solution) to expose the P-type silicon layer 24 and N⁺-type silicon layer 25, as shown in FIGS. 3C-3F. The first and second silicon oxide layers 31 and 32 respectively have a thickness of 1-20 nm. In one embodiment, the first and second silicon oxide layers 31 and 32 are formed with a CVD (Chemical Vapor Deposition) method according to the reaction equation:

Si(OC₂H₅)₄(g)→SiO₂(s)+4C₂H₄(g)+2H₂O₂(g).

The objective of forming the first and second silicon oxide layers 31 and 32 is to achieve the following advantages. Firstly, the first and second silicon oxide layers 31 and 32 can function as the passivation layers of the first and second silicon layers 22 and 23 to bond the dangling bonds of the first and second silicon layers 22 and 23 during the ion implantation, whereby is reduced the dangling bonds on the surfaces of the first and second silicon layers 22 and 23, enhanced the structural strength, promoted the yield and completeness of the silicon heterojunction solar cells and increased the photoelectric conversion efficiency. Secondly, the first and second silicon oxide layers 31 and 32 can adjust and control the concentration distribution and penetration depth of the implanted ions in the P-type silicon layer 24 and N⁺-type silicon layer 25 because the implanted ions penetrate the first and second silicon oxide layers 31 and 32 and have a Gaussian distribution on the first and second silicon layers 22 and 23. Thirdly, the first and second silicon oxide layers 31 and 32 can eliminate the unwanted ions and vacancies. The unnecessary vacancies and lighter ions have a shallow penetration depth and are distributed over the first and second silicon oxide layers 31 and 32 during the ion implantation. Thus the unwanted implanted ions or are also removed by etching the first and second silicon oxide layers 31 and 32.

Next, as shown in FIG. 3G, form a first TCO (Transparent Conductive Oxide) layer 26 on the P-type silicon layer 24 to function as an anti-reflection layer of the light-incident surface and a current collection layer. The first TCO layer 26 is made of but not limited to ITO (Indium Tin Oxide). A second TCO layer 27 may be selectively formed on the external side of the N⁺-type silicon layer 25 to function as another current collection layer. The second TCO layer 27 may be made of the same material as the first TCO layer 26. Then, as shown in FIG. 3H, respectively form a first electrode layer 28 and a second electrode layer 29 on the external sides of the first TCO layer 26 and the second TCO layer 27 to function as the electric contacts of the silicon heterojunction solar cell.

The method for fabricating a silicon heterojunction solar cell of the present invention can accurately control the doped concentrations of the P-type silicon layer 24 and the N⁺-type silicon layer 25 even though they are very thin. Further, the present invention uses the silicon oxide layers to improve the quality of the thin films of the P-type silicon layer 24 and the N⁺-type silicon layer 25. Furthermore, the present invention can cooperate with a large-area ion implanter to increase the implantation speed, implantation accuracy, yield rate and photoelectric conversion efficiency at a lower cost.

The P-N-N+ structure based on the N-type crystalline silicon substrate is used to exemplify the present invention in the above description. However, an N-P-P+ structure based on a P-type crystalline silicon substrate may also achieve the objective of the present invention via adjusting the doped electricity and the concentration thereof.

The embodiments described above are only to exemplify the present invention but not to limit the scope of the present invention. Any equivalent modification or variation according to the specification and drawings is to be also included within the scope of the present invention.

What is claimed is:

1. A method for fabricating a silicon heterojunction solar cell comprising steps of:
preparing a first conductive crystalline silicon substrate;
respectively forming a first silicon layer and a second silicon layer on two sides of the first conductive crystalline silicon substrate, wherein a silicon heterojunction is formed between the first silicon layer and the first conductive crystalline silicon substrate, and another silicon heterojunction is formed between the second silicon layer and the first conductive crystalline silicon substrate;
respectively ion-implanting the first silicon layer and the second silicon layer to form a second conductive silicon layer on a portion of an external side of the first silicon layer and form a first conductive heavily-doped silicon layer on a portion of an external side of the second silicon layer;
forming a first TCO (Transparent Conductive Oxide) layer on the second conductive silicon layer; and
respectively forming a first electrode layer and a second electrode layer on the first TCO layer and the first conductive heavily-doped silicon layer.

2. The method for fabricating the silicon heterojunction solar cell according to claim 1 further comprises a step of forming a second TCO layer on the first conductive heavily-doped silicon layer before the second electrode layer is formed on the first conductive heavily-doped silicon layer.

3. The method for fabricating the silicon heterojunction solar cell according to claim 1, wherein the first conductive crystalline silicon substrate is an N-type single crystalline silicon substrate, the second conductive silicon layer is a P-type silicon layer, and the first conductive heavily-doped silicon layer is an N⁺-type silicon layer.

4. The method for fabricating the silicon heterojunction solar cell according to claim 1, wherein the first silicon layer and the second silicon layer are both intrinsic amorphous silicon layers.

5. The method for fabricating the silicon heterojunction solar cell according to claim 1, wherein the first silicon layer and the second silicon layer are formed by a CVD (Chemical Vapor Deposition) method simultaneously.

6. The method for fabricating the silicon heterojunction solar cell according to claim 1 further comprises a step of undertaking a high-temperature thermal annealing after the second conductive silicon layer and the first conductive heavily-doped silicon layer are ion implanted.

7. A method for fabricating a silicon heterojunction solar cell comprising steps of:
preparing a first conductive crystalline silicon substrate;
respectively forming a first silicon layer and a second silicon layer on two sides of the first conductive crystalline silicon substrate, wherein a silicon heterojunction is formed between the first silicon layer and the first conductive crystalline silicon substrate, and another silicon heterojunction is formed between the second silicon layer and the first conductive crystalline silicon substrate;
respectively forming a first silicon oxide layer and a second silicon oxide layer on the first silicon layer and the second silicon layer;
respectively ion-implanting the first silicon layer and the second silicon layer to form a second conductive silicon layer on a portion of an external side of the first silicon layer and form a first conductive heavily-doped silicon layer on a portion of an external side of the second silicon layer;
removing the first silicon oxide layer and the second silicon oxide layer to expose the second conductive silicon layer and the first conductive heavily-doped silicon layer;
forming a first TCO (Transparent Conductive Oxide) layer on the second conductive silicon layer; and
respectively forming a first electrode layer and a second electrode layer on the first TCO layer and the first conductive heavily-doped silicon layer.

8. The method for fabricating the silicon heterojunction solar cell according to claim 7 further comprises a step of forming a second TCO layer on the first conductive heavily-doped silicon layer before the second electrode layer is formed on the first conductive heavily-doped silicon layer.

9. The method for fabricating the silicon heterojunction solar cell according to claim 7, wherein the first conductive crystalline silicon substrate is an N-type single crystalline silicon substrate, the second conductive silicon layer is a P-type silicon layer, and the first conductive heavily-doped silicon layer is an N⁺-type silicon layer.

10. The method for fabricating the silicon heterojunction solar cell according to claim 7, wherein the first silicon layer and the second silicon layer are both intrinsic amorphous silicon layers.

11. The method for fabricating the silicon heterojunction solar cell according to claim 7, wherein the first silicon layer and the second silicon layer are formed by a CVD (Chemical Vapor Deposition) method simultaneously.

12. The method for fabricating the silicon heterojunction solar cell according to claim 7 further comprises a step of undertaking a high-temperature thermal annealing after the second conductive silicon layer and the first conductive heavily-doped silicon layer are ion implanted.

13. A method for fabricating a silicon heterojunction solar cell comprising steps of:
preparing an N-type single crystalline silicon substrate;
respectively forming a first intrinsic amorphous silicon layer and a second intrinsic amorphous silicon layer on two sides of the N-type single crystalline silicon substrate;
respectively ion-implanting the first intrinsic amorphous silicon layer and the second intrinsic amorphous silicon layer to form a P-type amorphous silicon layer on a portion of an external side of the first intrinsic amorphous silicon layer and form an N⁺-type amorphous silicon layer on a portion of an external side of the second intrinsic amorphous silicon layer;
forming a first TCO (Transparent Conductive Oxide) layer on the P-type amorphous silicon layer; and
respectively forming a first electrode layer and a second electrode layer on the first TCO layer and the N⁺-type amorphous silicon layer.
